(19) United States
(12) Patent Application Publication
(10) Pub. No.: US 2018/0352654 A1
(43) Pub. Date: Dec. 6, 2018

(54) GALLIUM-CONTAINING ANISOTROPICALLY CONDUCTIVE FILM

(71) Applicant: Microsoft Technology Licensing, LLC, Redmond, WA (US)

(72) Inventor: Andrew L. FASSLER, Pittsburgh, PA (US)

(73) Assignee: Microsoft Technology Licensing, LLC, Redmond, WA (US)

(21) Appl. No.: 15/610,512

(22) Filed: May 31, 2017

(51) Int. Cl. H05K 1/09; H05K 1/02; H05K 1/11; H05K 1/14; H05K 3/46

(52) U.S. Cl. CPC H05K 1/092; H05K 1/028; H05K 2201/032; H05K 1/144; H05K 3/46; H05K 1/11

(57) ABSTRACT

Examples are disclosed that relate to anisotropically conductive materials. In one example, a hardenable paste is configured to form an anisotropically conductive junction between abutting conductor contacts of first and second electronic circuit components. The hardenable paste comprises a hardenable matrix and a plurality of particles of a gallium-containing metal dispersed within the hardenable matrix.

### BACKGROUND

Anisotropically conductive materials are used to form electrical connections between contacts on adjoining components. An anisotropically conductive material may comprise a hardenable matrix in which a dispersion of conductive particles is mixed at a sufficiently low concentration to avoid forming conductive paths through the matrix when not placed between contacts. When placed between contacts, pressure may be applied such that the conductive particles electrically bridge the gap between the contacts, thereby establishing electrical conductivity between the contacts while avoiding shorting to adjacent contacts. The material may then be hardened to fix the electrical connection.

### SUMMARY

Examples are disclosed that relate to anisotropically conductive materials. One aspect of this disclosure is directed to a hardenable paste configured to form an anisotropically conductive junction between abutting conductor contacts of first and second electronic circuit components. The hardenable paste comprises a hardenable matrix and a plurality of particles of a gallium-containing metal dispersed within the hardenable matrix.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 shows aspects of an example electronic device in the form of a head-mounted display device.

FIG. 2 shows aspects of an example electronic circuit of an electronic device.

FIGS. 3A and 3B show aspects of an example interface between an electronic circuit component and a circuit board of an electronic device.

FIG. 4 schematically shows aspects of an example hardenable paste configured to form an anisotropically conductive junction between abutting conductor contacts of an electronic circuit.

FIGS. 5 and 6 schematically show example particles of the hardenable paste of FIG. 4.

FIG. 7 illustrates an example process of manufacture of an electronic circuit using an anisotropically conductive hardenable paste.

### DETAILED DESCRIPTION

Aspects of this disclosure will now be described by example, and with reference to the drawing figures listed above. Components, process steps, and other elements that may be substantially the same in one or more embodiments are identified coordinately and described with minimal repetition. It will be noted, however, that elements identified coordinately may also differ to some degree. It will be further noted that the drawing figures are schematic and generally not drawn to scale. Rather, the various drawing scales, aspect ratios, and numbers of components shown in the figures may be purposely distorted to make certain features or relationships easier to see.

Some electronic devices, such as portable, handheld, and wearable electronic devices, may be subject to significant and/or repeated mechanical stresses in intended use scenarios. Moreover, the desire to pack increasing functionality into such devices—despite their limited size means that almost every portion of a device may have functional componentry mounted thereon. As a result, functional components that in the past were isolated from mechanical stress may now be subject to stress. When a functional electronic device component is too highly stressed, it may lose electrical contact with the circuit board to which it is mounted, causing device failure.

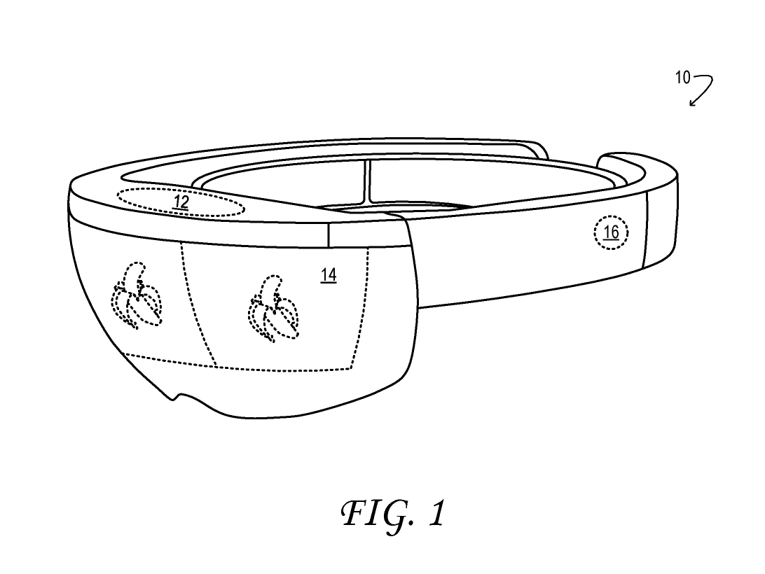

Accordingly, examples are disclosed that relate to anisotropically conductive materials that may help to avoid such damage to an electrical connection. Prior to discussing example materials, FIG. 1 shows aspects of an example electronic device 10 in the form of a head-mounted display device. The electronic device includes a plurality of electronic circuits and electronic circuit components, which may be separate or interconnected. In the illustrated example, the electronic device includes a computing system 12, a stereoscopic near eye display projector 14, and stereophonic headphones 16.

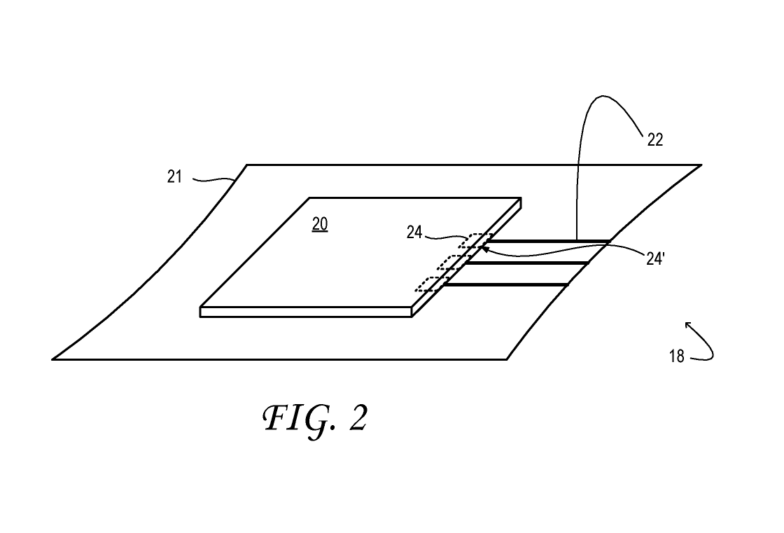

FIG. 2 shows an example electronic circuit 18 of electronic device 10. Electronic circuit 18 includes an example electronic circuit component 20 joined to a circuit board 21. Supporting a plurality of conductive traces 22, the circuit board 21 is also an electronic circuit component. Example electronic circuit component 20 may represent any suitable electronic circuit component. While depicted as a packaged integrated circuit, it will be understood that discrete electronic components (transistor, diode, resistor, capacitor, inductor, antenna, sensor, electromechanical relay, LED, laser die, loudspeaker, motor, piezoelectric element, electromechanical transducer, etc.) may be joined to a circuit board similarly.

Circuit board 21 may be a rigid printed circuit board (PCB), a bendable PCB, or a fully flexible PCB. Other circuit board examples include flexible ribbon cable (e.g. such as that usable to connect a moving print head to stationary inkjet printer logic), and elastomeric insulators with conductive traces embedded therein. Fully flexible PCBs may incorporate polyimide-flex, silicone, or stretch-to-flex materials, for example. In some implementations, other electronic circuit components 20 may also be flexible.

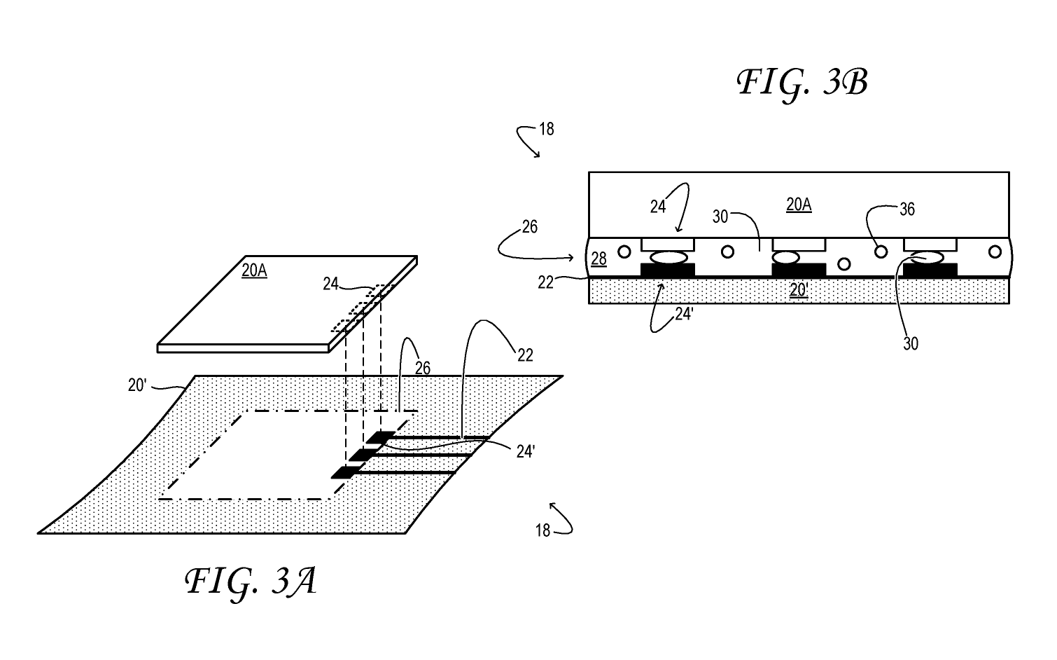

FIGS. 3A and 3B show, in further detail, aspects of an interface between electronic circuit component 20 and circuit board 21. The electronic circuit component includes a series of locally planar conductor contacts 24, which also may be referred to as pads. Circuit board 21 includes a complementary series of locally planar conductor contacts 24′. As shown in the drawing, the conductor contacts of the electronic circuit component abut the complementary conductor contacts of the circuit board to form a plurality of closed conduction paths between the electronic circuit component and the circuit board. In this manner, the various electronic circuit components 20 mounted to circuit board 21 are electrically interconnected.

Arranged between conductor contacts 24 of electronic circuit component 20 and the corresponding, abutting conductor contacts 24′ of circuit board 21 is a hardened, anisotropically conductive film 26. The hardened film includes a hardened matrix 28, and dispersed within the hardened matrix, a bridging metal 30 that fills the narrow space between the abutting conductor contacts, providing electrical conduction therebetween. The hardened film is prepared by hardening an unhardened film, which is deposited between electronic circuit component 20 and circuit board 21 and hardened as the electronic circuit component and circuit board are pressed together. The unhardened film is comprised of a hardenable paste comprising conductive particles configured to form an anisotropically conductive junction between each pair of abutting conductor contacts. To this end, the hardenable paste may be applied onto any suitable surface—e.g., circuit board 21. When the unhardened film hardens, it transforms into a hardened film that joins the electronic circuit component 20 to circuit board 21 and provides electrical conduction between the abutting conductor contacts thereof. It will be noted that the term ‘hardened’ is a relative term that merely describes the hardness of the film relative to its initial, hardenable state. In some implementations, the ‘hardened’ film may retain significant flexibility.

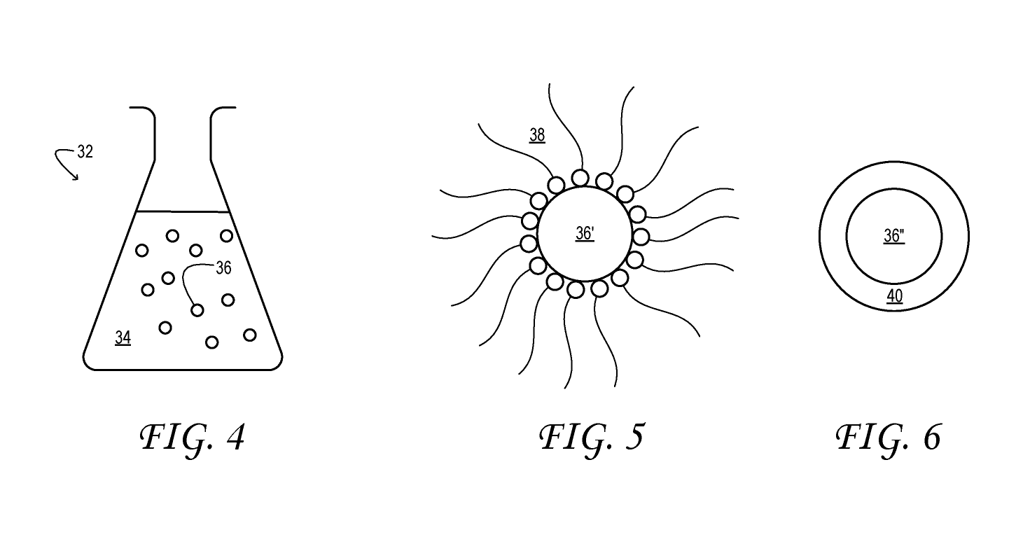

FIG. 4 shows aspects of hardenable paste 32 in one example embodiment. The hardenable paste includes a hardenable matrix 34 and a plurality of particles 36 dispersed within the hardenable matrix. The hardenable matrix may be a liquid, gel, or have any other suitable form prior to hardening. In some examples, the hardenable matrix may be curable—viz., curable thermally or upon addition of or exposure to a curing agent. In some examples, the curing agent may be air. In some examples, the curing agent may be photochemically or thermally activated. This variant is relevant to implementations in which the circuit board 21 is transparent to the radiation used in curing. In variants in which the hardenable paste is to be cured, the hardenable matrix may include an uncured polymer resin—e.g., an epoxy, acrylate, or urethane resin. In other examples, the hardenable matrix may be dryable by evaporation of volatile solvent included therein. This variant is relevant to implementations in which circuit board 21 is porous. In these and other examples, the hardenable matrix may take the form of an adhesive configured to physically adhere electronic circuit component 20 to circuit board 21.

Islands of bridging metal 30 that bridge the abutting conductor contacts 24 and 24′ are formed by compression of particles 36 as electronic circuit component 20 is compressed against circuit board 21. In some anisotropically conductive materials, the particles may be formed from a hard though somewhat malleable bridging metal, such as silver. In such materials, minute mechanical stress at the junction between electronic circuit component 20 and circuit board 21 may cause the compressed bridging metal to detach from either or both of the abutting conductor contacts that it bridges. This, in turn, may cause a loss of conduction between the conductor contacts. In some scenarios, thermal cycling from repeated use and disuse of electronic device 10 may cause sufficient mechanical strain to detach the bridging metal. The risk of detachment is further amplified if either the electronic component or circuit board is designed to be flexible and subject to mechanical strain during ordinary use.

Thus, the particles 36 within hardenable paste 32 may comprise a gallium-containing metal, such as elemental gallium (Ga), eutectic gallium-indium (GaIn), gallium-tin (GaSn) and/or galinstan (GaInSn), for example. The gallium-containing metals are more malleable than silver at the typical operating temperatures of electronic device 10 GaIn and GaInSn, for example, being liquids at 25° C. As such, the bridging metal formed upon compression of the unhardened film between electronic circuit component 20 and the circuit board 21 provides a flowable contact between abutting conductor contacts. Even in the presence of mechanical strain, the flowable contact remains wetted to both conductor contacts, maintaining electrical conduction therebetween.

The term ‘particle’ is used herein to refer to an individual microscopic body of bridging metal 30 dispersed in hardenable matrix 34, even if the bridging metal is liquid at the temperature at which hardenable paste 32 is prepared, stored, and/or used. As such, the term ‘particle’ includes and encompasses the related terms ‘droplet’ or ‘corpuscle’.

Continuing, good adhesion between the bridging metal and conductor contacts 24 and 24′ prevents the bridging metal (even if liquid) from flowing laterally to an adjacent conductor contact before hardenable matrix 34 hardens. In some implementations, one or both of the abutting conductor contacts may be modified so as to control the wettability thereon of the gallium-containing bridging metal. Moderately strong surface wetting is desirable, as would be observed for gallium-containing bridging metals wetting to gold or silver conductor contacts. On other metals, such as aluminum (and to some degree copper), the gallium-containing metal may wet the conductor contact so vigorously as to diffuse through the grain boundaries of the metal of the contact conductor. Accordingly, either or both conductor contacts 24 and 24′ may include a thin overlayer of a metal which is wettable but resistant to diffusion by the gallium-containing metal. In other words, the metal of the overlayer may fail to chemically alloy the gallium-containing metal due to thermodynamics, or may exhibit a high kinetic barrier to alloying, such that diffusion does not occur within the useful lifetime of the electronic circuit components joined by the paste. Examples include overlayers of one or more of nickel, titanium, and tantalum and alloys thereof. In other examples, a thin overlayer of gold, indium, tin, palladium, platinum, or any other protective metal may be used. An overlayer may be formed by electroplating, electroless deposition, or chemical vapor deposition, for example.

As noted above, hardenable paste 32 may include gallium-containing particles 36 dispersed within an uncured polymer resin as the hardenable matrix. Techniques such as shear mixing, ball mixing, and the like may be used to adjust the average size of the particles dispersed in the matrix to a desired, predetermined average size. The predetermined average size may be 5 to 40 micrometers (μm) in some implementations, although other size ranges are also envisaged. More generally, the predetermined average size may be based on the feature size of the components being joined. In some implementations, ultrasound may be used to form a dispersion of gallium-containing metal having the desired average particle size. After sheer mixing or sonication, the dispersion may be diluted with additional uncured polymer resin to achieve a bridging metal concentration suitable for anisotropic conductive film applications.

In some examples, a hardenable paste containing dispersed gallium-containing metal particles 36 may be stored and applied at reduced temperature to discourage coalescence or aggregation of the particles. Then, using a controlled temperature program, the unhardened film prepared via application of the hardenable paste may be compressed between electronic circuit component 20 and circuit board 21, and concurrently or subsequently cured. Accordingly, in such examples, the gallium-containing metal particles may be solid prior to and/or during the compression stage, but liquid after the compression stage.

In some implementations, as shown in FIG. 5, particles 36′ of the gallium-containing metal may be encapsulated by a surfactant shell 38. In other implementations, particles 36″ may be encapsulated by a rigid shell 40, as shown in FIG. 6. The coalescence retarding properties of the surfactant or rigid shell may eliminate the need to store hardenable paste 32 or compress the unhardened film at reduced temperature. Example surfactant shells may include long chain aliphatic thiols associated via spontaneous molecular self-assembly. Shells comprising metals selected to not alloy the gallium-containing metal—metals such as nickel, for example—may be formed by electroless deposition onto gallium-containing metal particles from the solution phase. In still other implementations, a polymer shell may be formed via emulsion polymerization initiated at the surface of the gallium-containing metal particles, the pre-polymer being supplied from the solution phase. In these and other examples, when shell supporting particles are compressed between abutting conductor contacts 24 and 24′, the shells break open and release a controlled amount of gallium-containing metal contained therein. The gallium-containing metal then serves as bridging metal 30.

The foregoing description and drawings should not be understood in a limiting sense, for numerous variations and extensions are contemplated as well. In some implementations, for instance, the gallium-containing metal itself may be formed in situ when an appropriate unhardened film is compressed between abutting conductor contacts. In this case, one or both of the abutting conductor contacts may include a metal that alloys the gallium-containing metal to form a liquid bridging metal between the conductor contacts. For instance, the conductor contacts may support a surface plating of indium and the particles may comprise solid gallium. In such examples, liquid eutectic Gain may form via an alloying reaction when the materials are brought into contact.

Although electronic device 10 is illustrated in FIG. 1 as a HMD device, the materials disclosed herein may be used in any suitable device. Examples include smart watches and fitness trackers (in which the entire watch band may be functionalized), flexible phones and tablet computers, flexible chips, and ribbon cable for inkjet printers, among others.

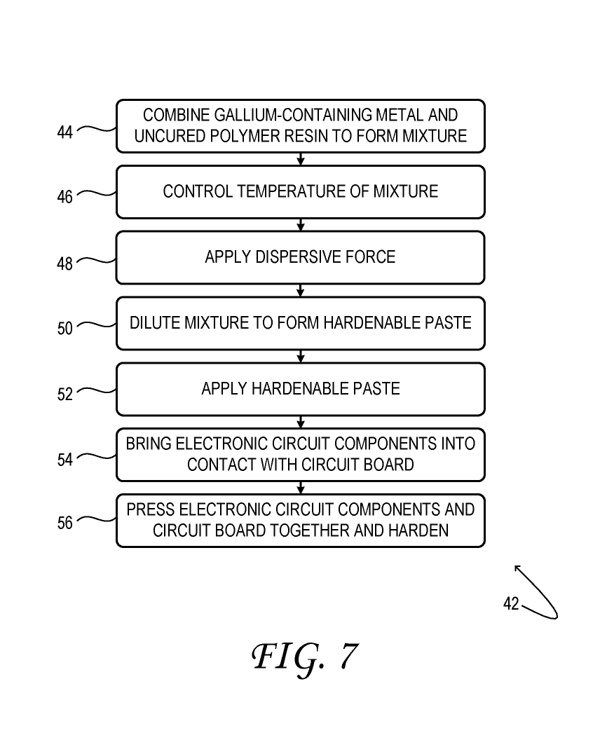

FIG. 7 illustrates an example method 42 of manufacture of an electronic circuit. At 44 of method 42, a gallium-containing metal and an uncured polymeresin are combined to form a mixture. At 46, the temperature of the mixture is controlled so that one or more of the gallium-containing metal and the uncured polymer resin is a liquid. In some examples, the temperature control may include an upward adjustment of the temperature from the temperature at which the mixture is initially formed, while in other examples, the gallium-containing metal may be liquid at room temperature or lower. At 48, dispersive force is applied to the mixture to disperse the gallium-containing metal into a plurality of particles of a predetermined size distribution suspended in the uncured polymer resin.

In some examples, the act of applying the dispersive force may include exposing the mixture to ultrasound. In some examples, the act of applying the dispersive force may include subjecting the mixture to shear mixing. At 50 the mixture is diluted with a suitable diluent (e.g., additional uncured polymer resin) to a predetermined concentration, thereby forming an uncured hardenable paste. The uncured hardenable paste may be stored for a period of time until needed. In some examples, a shelf life of the uncured hardenable paste may be in the range of 3 to 12 months, depending on the materials used and the storage conditions (e.g. under refrigeration).

At 52 the uncured hardenable paste is spread out on a two-dimensional surface, such as a component joining surface of a circuit board. At 54 the various electronic circuit components to be joined to the circuit board are brought into contact with the side of the film opposite the circuit board. At 56 the electronic circuit components and circuit board are pressed together under conditions that promote curing of the uncured hardenable paste. In some implementations, controlled and/or elevated temperature conditions may be used to promote curing. In some implementations, the circuit board may be exposed to curing radiation, such as ultraviolet radiation.

Another example provides a hardenable paste configured to form an anisotropically conductive junction between abutting conductor contacts of first and second electronic circuit components. The hardenable paste comprises a hardenable matrix and a plurality of particles of a gallium-containing metal dispersed within the hardenable matrix.

In some implementations, the hardenable matrix includes one or more of a liquid, a gel, and an adhesive. In some implementations, the hardenable matrix includes an uncured polymer resin. In some implementations, the gallium-containing metal includes one or more of gallium, eutectic gallium-indium, gallium-tin, and galinstan. In some implementations, the gallium-containing metal is a liquid at 25° C. In some implementations, each of the particles is encapsulated by a surfactant. In some implementations, each of the particles is encapsulated by a rigid shell. In some implementations, the rigid shell includes a metal that does not alloy the gallium-containing metal. In some implementations, the rigid shell includes a polymerized shell.

Another example provides an electronic circuit comprising first and second electronic circuit components and a hardened film. The first electronic circuit component has a first conductor contact; the second electronic circuit component has a second conductor contact abutting the first conductor contact. Arranged between the first and second conductor contacts, the hardened film comprises a hardened matrix and a plurality of particles of a gallium-containing metal dispersed within the hardened matrix. The hardened film joins the first and second electronic circuit components and provides electrical conduction between the first and second conductor contacts.

In some implementations, the second electronic circuit component is one of a plurality of electronic circuit components joined to the first electronic circuit component. In some implementations, one or more of the first and second electronic circuit components is a circuit board having a plurality of conductive traces. In some implementations, one or more of the first and second electronic circuit components is flexible. In some implementations, the hardened paste is arranged as an anisotropically conductive film, in which a bridging metal formed by compression of the particles bridges the first and second conductor contacts. In some implementations, one or more of the first and second conductor contacts includes an overlayer of metal wettable by the gallium-containing metal. In some implementations, the overlayer includes one or more of nickel, gold, indium, and tin. In some implementations, one or more of the first and second conductor contacts includes a metal that alloys the gallium-containing metal to form a liquid bridging metal between the first and second contact conductors.

Another example provides a method of making a hardenable paste usable to form an anisotropically conductive junction between abutting conductor contacts of first and second electronic circuit components. The method comprises: combining a gallium-containing metal and an uncured polymer resin to form a mixture; controlling a temperature of the mixture so that one or more of the gallium-containing metal and the uncured polymer resin is a liquid; and applying dispersive force to the mixture to disperse the gallium-containing metal into a plurality of particles of a predetermined size distribution suspended in the uncured polymer resin.

In some implementations, applying the dispersive force includes exposing the mixture to ultrasound. In some implementations, applying the dispersive force includes subjecting the mixture to shear mixing, the method further comprising diluting the mixture.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A hardenable paste configured to form an anisotropically conductive junction between abutting conductor contacts of first and second electronic circuit components, the hardenable paste comprising:
a hardenable matrix comprising a nonconductive curable adhesive; and
a plurality of particles of a gallium-containing metal dispersed within the hardenable matrix at a sufficiently low concentration to avoid forming a conductive path through the hardenable matrix when not placed between the abutting conductor contacts.

2. The hardenable paste of claim 1 wherein the hardenable matrix includes one or more of a liquid and a gel.

3. The hardenable paste of claim 1 wherein the nonconductive curable adhesive includes an uncured polymer resin.

4. The hardenable paste of claim 1 wherein the gallium-containing metal includes one or more of gallium, eutectic gallium-indium, gallium-tin, and gallium-indium-tin.

5. The hardenable paste of claim 1 wherein the gallium-containing metal is a liquid at 25° C.

6. The hardenable paste of claim 1 wherein each of the particles is encapsulated by a surfactant.

7. The hardenable paste of claim 1 wherein each of the particles is encapsulated by a rigid shell.

8. The hardenable paste of claim 7 wherein the rigid shell includes a metal that does not alloy the gallium-containing metal.

9. The hardenable paste of claim 7 wherein the rigid shell includes a polymerized shell.

10. An electronic circuit comprising:
a first electronic circuit component having a first conductor contact;
a second electronic circuit component having a second conductor contact abutting the first conductor contact; and
arranged between the first and second conductor contacts, a hardened film comprising a hardened matrix and a plurality of particles of a gallium-containing metal dispersed within the hardened matrix, the hardened film joining the first and second electronic circuit components and providing electrical conduction between the first and second conductor contacts.

11. The electronic circuit of claim 10 wherein the second electronic circuit component is one of a plurality of electronic circuit components joined to the first electronic circuit component.

12. The electronic circuit of claim 10 wherein one or more of the first and second electronic circuit components is a circuit board having a plurality of conductive traces.

13. The electronic circuit of claim 10 wherein one or more of the first and second electronic circuit components is flexible.

14. The electronic circuit of claim 10 wherein the hardened paste is arranged as an anisotropically conductive film, in which a bridging metal formed by compression of the particles bridges the first and second conductor contacts.

15. The electronic circuit of claim 10 wherein one or more of the first and second conductor contacts includes an overlayer of metal wettable by the gallium-containing metal.

16. The electronic circuit of claim 15 wherein the overlayer includes one or more of nickel, gold, indium, and tin.

17. The electronic circuit of claim 10 wherein one or more of the first and second conductor contacts includes a metal that alloys the gallium-containing metal to form a liquid bridging metal between the first and second contact conductors.

18. A method of making a hardenable paste usable to form an anisotropically conductive junction between abutting conductor contacts of first and second electronic circuit components, the method comprising:
combining a gallium-containing metal and an uncured polymer resin to form a mixture;
controlling a temperature of the mixture so that one or more of the gallium-containing metal and the uncured polymer resin is a liquid; and
applying dispersive force to the mixture to disperse the gallium-containing metal into a plurality of particles of a predetermined size distribution suspended in the uncured polymer resin.

19. The method of claim 18 wherein applying the dispersive force includes exposing the mixture to ultrasound.

20. The method of claim 18 wherein applying the dispersive force includes subjecting the mixture to shear mixing, the method further comprising diluting the mixture.
